(19) United States
(12) Patent Application Publication
(10) Pub. No.: US 2011/0221460 A1
(43) Pub. Date: Sep. 15, 2011

(54) Integrated Circuit Arrangement Having a Defect Sensor

(76) Inventors: Heinrich Trebo, Hitzendorf (AT); Manfred Oswald, Graz (AT); Valentin Cee, Eggersdorf (AT)

(21) Appl. No.: 12/721,320

(22) Filed: Mar. 10, 2010

(51) Int. Cl. G01R 31/02; G01R 31/3187

(52) U.S. Cl. 324/750.3

(57) ABSTRACT

The present disclosure relates to an integrated circuit arrangement. The circuit arrangement includes a semiconductor body having a first surface and defining a vertical direction running perpendicular to the first surface. At least one sensor line is at least partially arranged above the first surface, and includes a first and a second contact terminal and at least one vertical line section coupled between the first and second contact terminals and running in the vertical direction. An evaluation circuit is coupled to the first and second contact terminals and adapted to evaluate an impedance of the at least one sensor line.

### TECHNICAL FIELD

Embodiments of the present invention relate to an integrated circuit arrangement, in particular to an integrated circuit arrangement having a defect sensor.

### BACKGROUND

Integrated circuit arrangements usually include a semiconductor body (die) and a wiring arrangement arranged above the semiconductor body. In the semiconductor body active areas of at least one semiconductor component, such as a transistor, a diode, a thyristor, etc., are integrated. Dependent on the type of integrated circuit only one component, such as a power transistor, a power diode, or a power thyristor, or several—up to several hundred thousand—components can be integrated in the semiconductor body. The wiring arrangement provides electrical connections from external terminals to the active areas and/or interconnects the different components.

Processes of manufacturing integrated circuit arrangements usually include manufacturing a number of identical circuit arrangements on a semiconductor wafer, and separating the wafer into the individual integrated circuits using cutting techniques, such as sawing, laser cutting, water cutting, etc. These cutting techniques impose mechanical stress on the wafer which may result in defects, such as cracks, in the integrated circuit. Dependent on how severe these defects are, these defects may result in a malfunction of the integrated circuit right after the manufacturing process, or may result in a malfunction after the integrated circuit has been in operation for a while.

Further, integrated circuits are often subject to significant temperature changes during their operation and/or subject to mechanical influences. These temperature changes or mechanical influences may result in mechanical stress, where such mechanical stress may result in new defects or may result in a further degradation of defects that were already introduced in the manufacturing process.

In order to detect defects in integrated circuits, crack sensors can be used. These sensors include a sensor line on a top surface of the integrated circuit, and an evaluation circuit that is adapted to detect interruption of the sensor line. However, such a sensor is only capable of detecting vertical cracks that extend through the sensor line.

There is, therefore, a need for an improved defect sensor, in particular a sensor that is capable of detecting lateral cracks in an integrated circuit.

### SUMMARY OF THE INVENTION

An embodiment of the present disclosure relates to an integrated circuit arrangement, including: a semiconductor body having a first surface, and defining a vertical direction running perpendicular to the first surface, and at least one sensor line that is at least partially arranged above the first surface. The sensor line includes: a first and a second contact terminal, and at least one vertical line section coupled between the first and second contact terminals and running in the vertical direction. An evaluation circuit is coupled to the first and second contact terminals, and is adapted to evaluate an impedance of the at least one sensor line.

Embodiments will now be explained in detail with reference to the drawings. The drawings serve to explain the basic principle, so that only aspects necessary for understanding the basic principle are illustrated. Same reference characters denote the same features throughout the drawings. The drawings are not necessarily to scale.

### BRIEF DESCRIPTION OF THE DRAWINGS

FIG. 1 illustrates a vertical cross section through an integrated circuit arrangement according to a first embodiment, with the integrated circuit arrangement including a sensor line;

FIG. 2 illustrates in detail a vertical cross section through a section of the sensor line;

FIG. 3 illustrates in detail a cross section through a section of the sensor line according to a further embodiment;

FIG. 4 illustrates a top view on an integrated circuit arrangement according to a first embodiment;

FIG. 5 illustrates a top view on an integrated circuit arrangement according to a second embodiment;

FIG. 6 illustrates a vertical cross section through an integrated circuit arrangement according to a further embodiment;

FIG. 7, that includes FIGS. 7A to 7E, illustrates cross sections through a section of a sensor line according to a further embodiment;

FIG. 8 illustrates a first example of an evaluation circuit; and

FIG. 9 illustrates a second example of an evaluation circuit.

### DETAILED DESCRIPTION OF ILLUSTRATIVE EMBODIMENTS

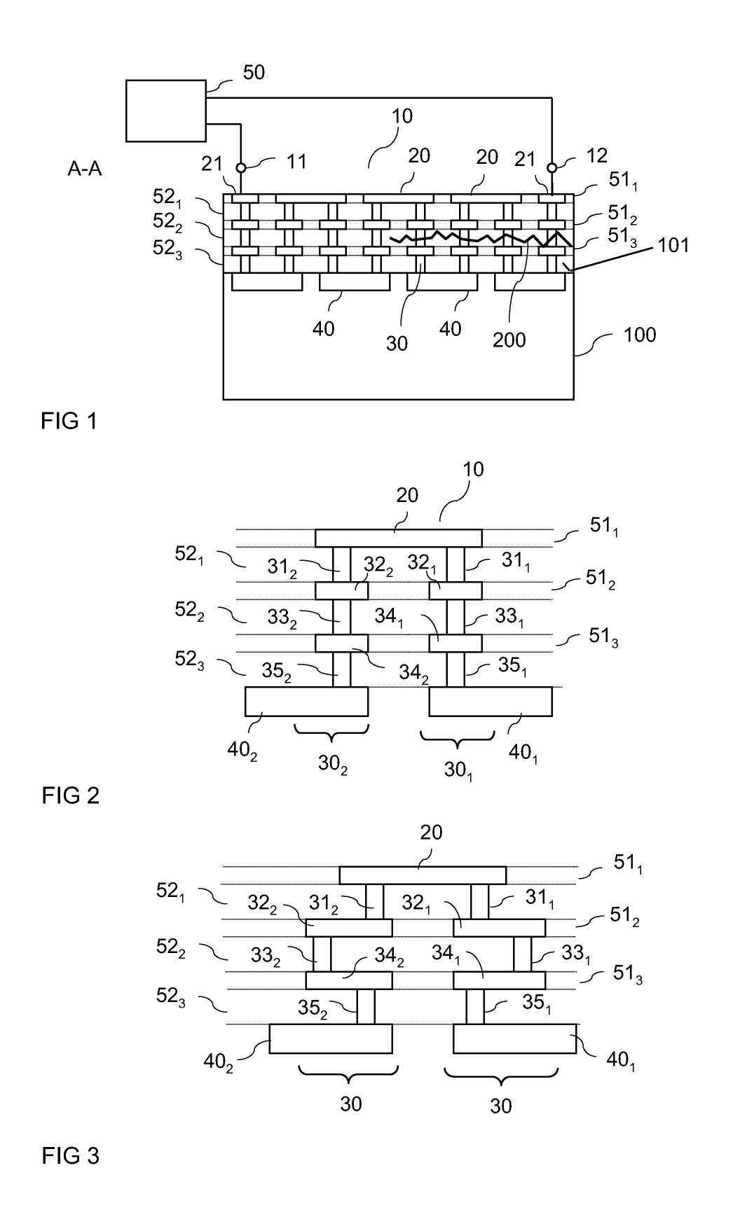

FIG. 1 schematically illustrates a vertical cross section through an integrated circuit arrangement according to a first embodiment. The circuit arrangement includes a semiconductor body (die) 100 that has a first surface 101, which will also be referred to as a front surface in the following. The semiconductor body may include a conventional semiconductor material, such as silicon, gallium arsenide (GaAs), or silicon carbide (SiC). Semiconductor body 100 may include a semiconductor substrate, or a semiconductor substrate on which additional semiconductor layers, such as epitaxial layers, are deposited. In case the semiconductor body 100 includes a substrate and epitaxial layers deposited on the substrate, one of the epitaxial layers forms the first surface 101 of the semiconductor body 100. Semiconductor body 100 could also be implemented as an SOI-substrate, which is a substrate that includes an insulation layer between two semiconductor layers.

The semiconductor body 100 includes active component areas of at least one semiconductor component. According to one embodiment, active areas of only one semiconductor component, such as a power transistor, like a MOSFET or an IGBT, a power diode, or a power thyristor, are integrated in the semiconductor body 100. According to another embodiment, active areas of several components, such as a power device and its drive circuit, are integrated in the semiconductor body. According to a further embodiment, active areas of complex integrated circuits, such as logic circuits or storage circuits, are integrated in the semiconductor body 100. The active areas of these components are not illustrated in the drawings, because the concept explained in the following of detecting a failure of the integrated circuit arrangement is independent of the type of semiconductor component that is integrated in the semiconductor body 100.

Referring to FIG. 1, the integrated circuit arrangement includes at least one sensor line 10 that is at least partially arranged above the first surface 101 of the semiconductor body 100. Sensor line 10 includes contact terminals 11, 12 that are electrically connected with each other through a number of line sections that are electrically connected with each other. An evaluation circuit 50 is coupled to the contact terminals 11, 12, and is adapted to evaluate an impedance of the sensor line 10. The sensor line 10 acts as a defect or crack sensor of the integrated circuit arrangement, where the impedance, in particular the ohmic resistance, of the sensor line 10 is dependent on whether there is a mechanical defect or crack that electrically changes the resistance of the sensor line or that interrupts the sensor line 10, or whether there is no mechanical defect changing or interrupting the sensor line 10.

The integrated circuit arrangement has a vertical direction, which is the direction running perpendicular to the first surface 101 of the semiconductor body 100. Sensor line 10 includes at least one vertical line section 30 that extends in the vertical direction of the integrated circuit arrangement. “To extend in the vertical direction” generally means that the vertical line section 30 geometrically extends in the vertical direction, and that a current that flows through the sensor line 10, when applying an electrical voltage between the contact terminals 11, 12, in the vertical line section 30 flows in the vertical direction. However, the vertical line section 30 is not necessarily perpendicular to the first surface 101, but, when geometrically dividing the vertical line section in a vertical component and a horizontal component, has a vertical component that is unequal to zero. Thus, the vertical line section 30 could be a line section that is perpendicular to the first surface 101, or a line section that is inclined compared to the first surface 101 and includes an angle with the first surface 101 between 90° and about 10°.

In the embodiment according to FIG. 1, a vertical line section 30 electrically connects one of a plurality of first horizontal line sections 20 with one of a plurality of second horizontal line sections 40. In the vertical section plane illustrated in FIG. 1 the first and second horizontal line sections 20, 40 and the vertical line sections 30 form a meander-like structure in which first horizontal line section 20, vertical line sections 30, and second horizontal line sections 40 are arranged alternatingly. The first horizontal line sections 20 and the second horizontal line sections 40 are arranged distant to one another in the vertical direction, where each of the first and second horizontal line sections 20, 40 essentially extends in a horizontal direction between two vertical line sections 30.

The first and second horizontal line sections 20, 40 and the vertical line sections 30 will now be explained in detail with reference to FIG. 2, in which a part of the sensor line 10 is illustrated in detail. FIG. 2 shows two second horizontal line sections 40₁, 40₂ and two vertical line sections 30₁, 30₂. The vertical line sections 30₁, 30₂ connect the second horizontal line sections 40₁, 40₂ with a first horizontal line section 20. Unless reference to a specific one of the second horizontal line sections 40₁, 40₂ or reference to a specific one of the vertical line sections 30₁, 30₂ is required, reference character 40 will in the following be used to refer to one of the second horizontal line sections, and reference character 30 will be used to refer to one of the vertical line sections. In the drawings subscript index “1” is used for the first vertical line section 30₁ and its parts, and subscript index “2” is used for the second vertical line section 30₂ and its parts.

In the embodiment illustrated in FIGS. 1 and 2, the vertical line sections 30 each include several vertical segments 31, 33, 35 where one of these vertical segments 31 contacts the first horizontal line section 20, another one of the vertical segments 35 contacts one of the second horizontal line sections 40, and where vertical segments that are arranged adjacent to one another are interconnected by connectors 32, 34.

In the embodiment illustrated in FIG. 2 the vertical segments 31, 33, 35 extend perpendicular to the first surface 101 (labeled in FIG. 1). However, this is only an example. According to another embodiment (not shown) there is an angle smaller than 90° between the vertical segments 31, 33, 35 and the first surface 101.

Although the vertical line sections 30 according to FIG. 2 each includes several—three in the present example—vertical line segments 31, 33, 35, it should be appreciated that the vertical line sections 30 could be implemented with any number ≧1 of vertical line segments as well.

According to an embodiment, sensor line 10 is at least partially arranged in a wiring arrangement above the first surface 101 of the semiconductor body 100. Wiring arrangements are commonly known and are used to connect active areas of semiconductor components integrated in a semiconductor body, such as semiconductor body 100, with external contact terminals of an integrated circuit arrangement, or are used to interconnect individual semiconductor components integrated in the semiconductor body. Wiring arrangements include a number of conduction layers, that are also referred to as metallization layers, and insulation layers, where the insulation layers serve to isolate two adjacent conduction layers from one another. In each of the conduction layers one or several connection lines are formed, where connection lines of one conduction layer can be connected with connection lines of an adjacent conduction layer through electrically conducting vias that extend through the insulation layer between the two conduction layers.

The sensor line 10 illustrated in FIGS. 1 and 2 is arranged in a wiring arrangement that includes three conduction layers 51₁, 51₂, 51₃, two insulation layers 52₁, 52₂ that isolate the conduction layers 51₁, 51₂, 51₃ from one another, and a further insulation layer 52₃ that separates one 51₃ of the conduction layers from the semiconductor body 100. The first horizontal line sections 20 are implemented in a first conduction layer 51₁, which will also be referred to as the upper conduction layer in the following. The vertical line segments 31, 33, 35 of the vertical line sections 30 are realized as electrically conducting vias that extend in a vertical direction through the insulation layers 52₁, 52₂, 52₃. The connectors 32, 34 are implemented in a second and a third conduction layer 51₂, 51₃ in the present embodiment.

The first and second horizontal line sections 20,40 and the vertical line sections 30 are made of electrically conducting materials, such as metals, like aluminum, copper, tungsten, titanium, or metal-alloys, where the same material can be used to implement the horizontal and vertical line sections, or where different materials may be used for these individual line sections.

In the embodiment illustrated in FIGS. 1 and 2 the second horizontal line sections 40 are doped semiconductor regions that are arranged in the semiconductor body below the surface 101 of the semiconductor body 100. These doped semiconductor regions are, for example, highly doped semiconductor regions. The doped semiconductor regions can be n-type or p-type semiconductor region.

Due to the presence of the vertical line sections 30, sensor line 10 is, in particular, useful in detecting so-called lateral cracks, which are cracks that extend in a lateral direction of the integrated circuit arrangement. A lateral crack 200 is schematically illustrated in FIG. 1. Such a lateral crack electrically interrupts the sensor line in a horizontal/lateral direction and, therefore, increases the ohmic resistance of the sensor line 10. Methods for evaluating the ohmic resistance of the sensor line 10 will be explained in further detail hereinbelow.

Integrated circuit arrangements, like the one that is schematically illustrated in FIG. 1, can be manufactured using a process that manufactures a plurality of identical integrated circuits on a semiconductor wafer, and that finally separates the wafer into the individual integrated circuits using mechanical cutting or separation methods, such as sawing, laser cutting, water cutting, etc. These mechanical separation methods may result in mechanical damages, such as cracks, of the individual integrated circuits, where these damages are to be detected using a sensor line, such as sensor line 10 illustrated before. Since mechanical damages that result from separating the wafer usually occur close to an edge of the integrated circuit, with the edge resulting from the separation process, the sensor line 10, according to one embodiment, is arranged close to the edge of the semiconductor body or the integrated circuit, respectively.

FIG. 3 illustrates a vertical cross section through a part of a sensor line 10 according to a further embodiment. While in the embodiment according to FIG. 2 the vertical line segments 31, 33, 35 of one vertical line section 30 are arranged in line with one another in the vertical direction, vertical line segments 31, 33, 35 in the embodiment according to FIG. 3 are arranged distant to one another in the horizontal direction. These vertical line segments 31, 33, 35 together with the connectors 32, 34 form a meander-like structure that extends in the vertical direction of the integrated circuit arrangement. In the embodiment according to FIG. 2 connectors 32, 34 can be implemented such that their horizontal dimensions correspond to the horizontal dimensions of the vias forming the vertical line segments 31, 33, 35. However, in order to compensate for alignment errors when producing the vertical line segments 31, 33, 35 the horizontal dimensions of the connectors 32, 34 can be larger than the horizontal dimensions of the vias 31, 33, 35.

In the embodiment according to FIG. 3 the horizontal dimensions of the connectors 32, 34 are selected such that one connector is capable of interconnecting the vertical line segments that are implemented in two adjacent insulation layers.

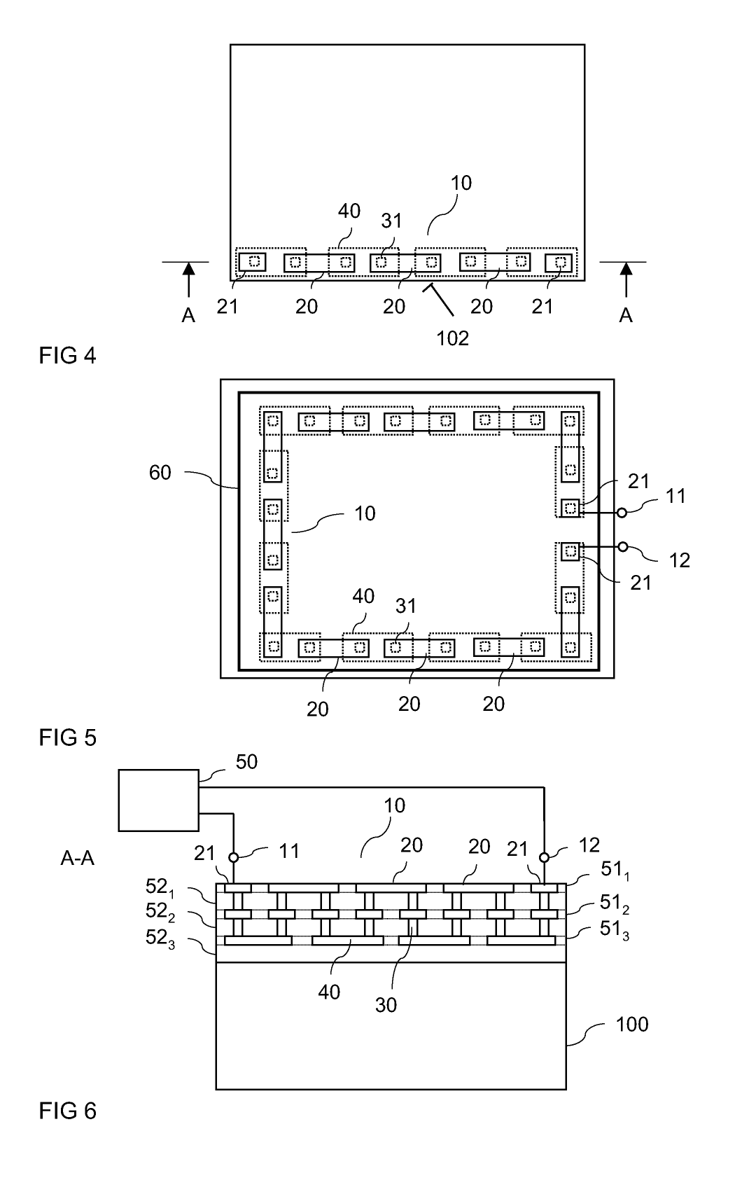

FIG. 4 illustrates a top view on an integrated circuit arrangement that has a sensor line 10 arranged close to one edge 102 of the semiconductor body 100 or the integrated circuit arrangement, respectively. In the top view illustrated in FIG. 4 the first horizontal line sections 20 are illustrated in solid lines. The vertical line segments 31 and the second horizontal line sections 40 that, in the vertical direction, are arranged below the first horizontal line sections 20 are illustrated in dotted lines in FIG. 4.

FIG. 4 illustrates only one sensor line 10 that is arranged along one edge 102 of the integrated circuit arrangement. According to a further embodiment (not illustrated) the integrated circuit arrangement includes at least one additional sensor line that is arranged close to another one of the edges of the integrated circuit arrangement. Sensor lines, such as sensor line 10 illustrated in FIGS. 1 and 4, are, however, not restricted to be arranged close to an edge of an integrated circuit arrangement. One or several sensor lines could of course also be arranged distant to edges of the integrated circuit arrangement.

FIG. 5 schematically illustrates a top view of an integrated circuit arrangement according to a further embodiment. In this embodiment the sensor line 10 in the horizontal plane has a ring-shaped geometry and extends along all four edges of the integrated circuit arrangement. However, the ring is not completely closed; there is a gap between connectors 21 that form the first and second contact terminals 11, 12. In the embodiment illustrated in FIG. 5 there is a gap in the horizontal direction. However, alternatively, there could also be a gap in the vertical direction (not shown).

Referring to FIG. 5, the integrated circuit arrangement optionally includes a seal-ring. Seal-rings protect integrated circuit arrangements from external influences, such as indiffusion of impurities in a lateral direction. Such seal-rings are commonly known, so that no further explanations are required in this regard. According to an embodiment sensor line 10, such as ring-shaped sensor line 10 according to FIG. 5, is arranged inside the seal-ring 60, i.e., seal-ring 60 is arranged between the sensor line 10 and the edge of the integrated circuit arrangement.

FIG. 6 schematically illustrates a vertical cross section though a further embodiment of an integrated circuit arrangement. The circuit arrangement is different from the one illustrated in FIGS. 1 and 2 in that the second horizontal line sections of sensor line 10 are not implemented as doped semiconductor regions but are implemented in one of the conduction layers, namely the third or lower conduction layer 51₃.

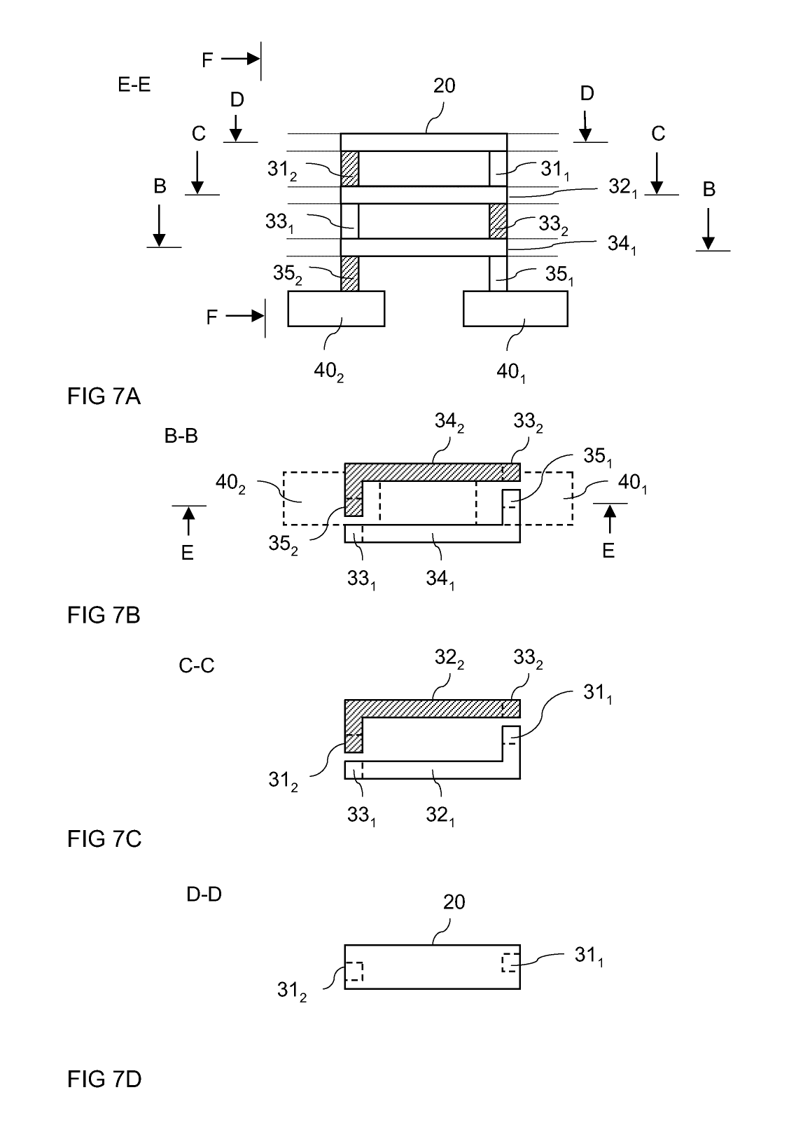

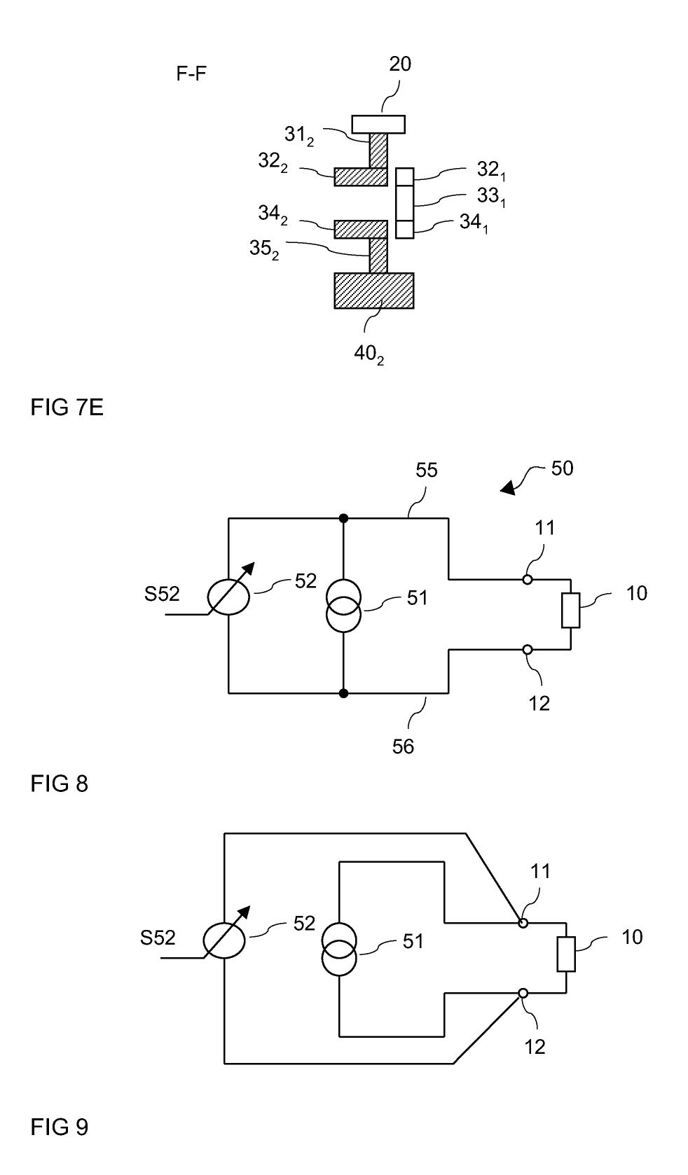

FIG. 7 that includes FIGS. 7A-7E includes a further embodiment of a sensor line 10 that includes vertical line sections that have a meander-like structure extending in the vertical direction. In FIG. 7 only two of such vertical line sections are illustrated, where the individual parts of a first one of these vertical line sections have reference characters with a subscript index “1”, and parts of the second vertical line sections have reference characters with a subscript index “2”. FIG. 7A illustrates a vertical cross section through an arrangement with the two vertical line sections, one first horizontal line section 20 and two second horizontal line sections 40₁,40₂. To ease understanding of the structure the parts of the second vertical line section are drawn to be shaded in FIG. 7.

FIG. 7B illustrates a horizontal cross section through connectors 34₁ in the third conduction layer, FIG. 7C illustrates a horizontal cross section through connectors 32₁ in the second conduction layer, and FIG. 7D illustrates a horizontal cross section through the first horizontal line section 20. FIG. 7E illustrates a vertical cross section in section line F-F illustrated in FIG. 7A.

The vertical line segments 31, 33, 35 and the connectors 32, 34 of one vertical line section form a meander-like structure, where the connectors 32, 34 essentially extend in that horizontal direction in which the first horizontal line section 20 extends and in which the two second horizontal line sections 40₁, 40₂ are distant from one another. The connectors 32, 34 each have an L-shape and are arranged distant to one another in a horizontal direction that is perpendicular to the horizontal direction in which the connectors mainly extend. Due to arranging the connectors 32₁ and 32₂ distant to one another and arranging connectors 34₁, 34₂ distant to one another a short-circuit between these connectors is prevented.

FIG. 8 illustrates a first embodiment of an evaluation circuit 50 that is adapted to evaluate the impedance, in particular, the ohmic resistance, of the sensor line 10. In FIG. 8 sensor line 10 is schematically illustrated as ohmic resistor connected between the contact terminals 11, 12. The evaluation circuit 50 according to the embodiment illustrated in FIG. 8 includes a current source 51 connected between the contact terminals 11, 12, and a voltage measuring device 52. Current source 51 is adapted to drive a measuring current through the sensor line 10, and the voltage measuring device is adapted to measure a voltage drop across the sensor line 10 resulting from the measuring current.

A control circuit (not shown) such as a microcontroller, may receive the measuring signal S52. By comparing the measuring signal S52 with previous measuring signal, or by comparing the measuring signal with a fixed reference value a fault of the sensor line 10 can be detected. The reference value is selected such that the voltage drop across the sensor line 10 rises above the measured voltage drop only when there is a defect of the sensor line 10, such as an interruption of the sensor line 10 due to a defect/crack of the integrated circuit arrangement.

Optionally the measuring signal S52 provided by the voltage measuring device is compared with a reference signal Vref provided by a reference signal source (not shown). For comparing the measurement signal and the reference signal Vref a comparator (not shown) can be used that provides an output signal that is dependent on the comparison result. According to an embodiment the output signal of the comparator assumes one of a normal level or a fault level, where the output signal assumes the fault level when the measured voltage drop across the sensor line 10 assumes a value that is higher than the reference value Vref. The reference value Vref is selected such that the voltage drop across the sensor line 10 rises above the measured voltage drop only when there is a defect of the sensor line 10, such as an interruption of the sensor line 10 due to a defect/crack of the integrated circuit arrangement.

In the embodiment according to FIG. 8 the voltage drop across the current source 51 is measured. However, in this example connection lines 55, 56 between the current source 51 and the contact terminals 11, 12 also contributes to the measuring result.

Thus, according to a further embodiment that is illustrated in FIG. 9, the voltage drop can directly be measured between the contact terminals 11, 12.

It goes without saying that driving a current through the sensor line 10 and evaluating the voltage drop resulting from the current flow is only one of a plurality of possible methods for evaluating the impedance of the sensor line 10.

Evaluation circuit 50, which is only schematically illustrated in FIG. 1, can be an external circuit, i.e., a circuit that is not integrated in the semiconductor body 100, but could also be a circuit that is integrated in the semiconductor body 100. In embodiments in which the evaluation circuit 50 is integrated in the semiconductor body 100 the evaluation circuit 50 can already be used for diagnosing the integrated circuit before separating a wafer that includes a plurality of identical integrated circuits, into the individual integrated circuits. By comparing an impedance value of the sensor line 10 of one particular integrated circuit before separating the wafer and after separating the wafer a first diagnosis can be performed. In case the impedance of the sensor line significantly changes when separating the wafer into the individual integrated circuits a defect, such as a crack, is likely to have occurred during the separation process.

The evaluation circuit 50 may of course also be used during operation of the chip for diagnosing the integrated circuit. In this case measurement values for the impedance of the sensor line 10 can also be compared with previous measurement values, or with fixed reference values, such as reference value Vref according to FIG. 9.

Finally it should be mentioned that features that have been explained with reference to one embodiment may also be combined with features of other embodiments, even if this has not been explicitly mentioned before.

What is claimed is:

1. An integrated circuit arrangement, comprising:
a semiconductor body having a first surface, and defining a vertical direction running perpendicular to the first surface;
at least one sensor line that is at least partially arranged above the first surface, and that comprises a first contact terminal and a second contact terminal, and at least one vertical line section coupled between the first and second contact terminals and running in the vertical direction;
an evaluation circuit coupled to the first and second contact terminals, and adapted to evaluate an impedance of the at least one sensor line.

2. The integrated circuit arrangement of claim 1, further comprising:
a wiring arrangement arranged on the first surface;
wherein the at least one sensor line is at least partially arranged in the wiring arrangement.

3. The integrated circuit arrangement of claim 2, further comprising:
at least one first horizontal line section;
at least one second horizontal line section;
wherein the at least one vertical line section is coupled between the at least one first horizontal line section and the at least one second horizontal line section.

4. The integrated circuit arrangement of claim 3, wherein the at least one first horizontal line section and the at least one second horizontal line section run essentially parallel to the first surface.

5. The integrated circuit arrangement of claim 3, wherein the at least one first horizontal line section and the at least one second horizontal line section are arranged distant to one another in the vertical direction.

6. The integrated circuit arrangement of claim 3, wherein the wiring arrangement comprises:
at least one first conduction layer;
at least one first insulation layer arranged between the at least one first conduction layer and the semiconductor body;
wherein the at least one first horizontal line section is arranged in the at least one first conduction layer, and
wherein the at least one vertical line section comprises a via in the at least one first insulation layer.

7. The integrated circuit arrangement of claim 6, wherein the at least one second horizontal line section is a doped semiconductor zone arranged in the semiconductor body.

8. The integrated circuit arrangement of claim 6, wherein the wiring arrangement further comprises:
at least one second conduction layer;
wherein the at least one second horizontal line section is arranged in the at least one second conduction layer.

9. The integrated circuit arrangement of claim 1, wherein the circuit arrangement further comprises:
an inner region and an edge region;
wherein the at least one sensor line is arranged in the edge region.

10. The integrated circuit arrangement of claim 1, wherein the evaluation circuit is integrated in the semiconductor body.

11. The integrated circuit arrangement of claim 1, wherein the at least one vertical line section comprises a plurality of vertical line segments that are electrically connected in series using connectors.

12. The integrated circuit arrangement of claim 11, wherein the plurality of vertical line segments are arranged in line with each other.

13. The integrated circuit arrangement of claim 11, wherein the plurality of vertical line segments and the connectors are designed such that the plurality of vertical line segments and the connectors form a meander-like structure.
